(19) United States
(12) Patent Application Publication
(10) Pub. No.: US 2025/0147147 A1
(43) Pub. Date: May 8, 2025

(54) SIGNAL PROCESSING DEVICE AND SIGNAL PROCESSING METHOD

(71) Applicant: Mitsubishi Electric Corporation, Tokyo (JP)

(72) Inventors: Tomoya YAMAOKA, Tokyo (JP); Satoshi KAGEME, Tokyo (JP)

(73) Assignee: Mitsubishi Electric Corporation, Tokyo (JP)

(21) Appl. No.: 19/012,429

(22) Filed: Jan. 7, 2025

Related U.S. Application Data
(63) Continuation of application No. PCT/JP2022/029599, filed on Aug. 2, 2022.

(51) Int. Cl. G01S 7/292; G01S 7/35

(52) U.S. Cl. CPC G01S 7/292; G01S 7/354

(57) ABSTRACT

A signal processing device includes: a signal acquisition unit that acquires an input signal; a signal extraction unit that extracts a specific signal by multiplying the input signal by a window function; a frequency conversion unit that performs frequency conversion on the extracted signal; and a signal output unit that outputs the frequency-converted signal, in which the window function includes one or a plurality of cos function terms in which at least one of the sign of a coefficient to multiply a cos function or a degree of the cos function is set in such a manner that both frequency resolution and a reduction amount of sidelobes fall within allowable ranges.

### CROSS REFERENCE TO RELATED APPLICATION

This application is a Continuation of PCT International Application No. PCT/JP2022/029599, filed on Aug. 2, 2022, which is hereby expressly incorporated by reference into the present application.

### TECHNICAL FIELD

The present disclosure relates to a signal processing device and a signal processing method.

### BACKGROUND ART

There is known signal processing technology of extracting a specific signal component included in a signal, performing frequency conversion on the extracted signal component, and performing frequency analysis on frequency conversion data of the signal component. For example, there is technology of using a window function in order to reduce sidelobes of the frequency component of a radio signal. Examples of the window function include a raised-cosine window described in Non-Patent Literature 1.

The raised-cosine window is a window function including a constant term and a term obtained by adding a cosine function (hereinafter, referred to as a cos function) multiplied by a positive coefficient for each constant period. In the raised-cosine window, cos function terms are linearly combined by multiplying the cos function by an appropriate coefficient value, whereby sidelobes of the frequency component of a signal extracted using the raised-cosine window can be reduced.

### CITATION LIST

### Non-Patent Literature

Non-Patent Literature 1: F. J. Harris, “On the Use of Windows for Harmonic Analysis With the Discrete Fourier Transform”, in proc. IEEE. vol. 66, no. 1, January 1978.

### SUMMARY OF INVENTION

### Technical Problem

The window functions in the related art, represented by the raised-cosine window, have a problem that when the sidelobe component in the frequency domain is reduced, the frequency resolution is reduced accordingly.

The present disclosure solves the above problem, and an object thereof is to obtain a signal processing device and a signal processing method capable of preferably trade-off between the frequency resolution and the sidelobe characteristics than the window functions in the related art can.

### Solution to Problem

A signal processing device according to the present disclosure includes: a processor; and a memory storing a program, upon executed by the processor, to perform a process: to acquire an input signal; to extract a specific signal by multiplying the input signal by a window function; to perform frequency conversion on the extracted signal; and to output the frequency-converted signal, wherein the window function comprises a synthesis of one or a plurality of cosine function terms, and the window function is obtained by multiplying a negative coefficient to the cosine function term selected from one or the plurality of cosine function terms so that zero value is set at a center of the window range and a peak power of a sidelobe corresponding to the cosine function term in a frequency domain is reduced, a reduction of a frequency resolution is suppressed, or both thereof more than that of multiplying positive values to all of the cosine function terms.

### Advantageous Effects of Invention

According to the present disclosure, by using the window function in which both the frequency resolution and the reduction amount of the sidelobes fall within the allowable ranges, the signal processing device according to the present disclosure can preferably trade-off between the frequency resolution and sidelobe characteristics than a case of using a window function of the related art, which is represented by a raised-cosine window.

### BRIEF DESCRIPTION OF DRAWINGS

FIG. 1 is a block diagram illustrating a configuration of a signal processing device according to a first embodiment.

FIG. 2 is a flowchart illustrating a signal processing method according to the first embodiment.

FIG. 3 is a graph showing the response in the frequency domain of a cos function term (cos(2πkx)) and the response in the frequency domain of sinc functions.

FIG. 4 is a graph showing superimposed representation of the response in the frequency domain of a cos function term (cos(2πx)) and the response in the frequency domain of a sine function.

FIG. 5 is a graph showing superimposed representation of the response in the frequency domain of a cos function term (cos(4πx)) and the response in the frequency domain of a sinc function.

FIG. 6 is a graph showing superimposed representation of the response in the frequency domain of a cos function term (cos(5πx)) and the response in the frequency domain of the sinc function.

FIG. 7 is a graph illustrating the shape of a window function in the first embodiment.

FIG. 8 is a graph showing superimposed representation of the response in the frequency domain of the window function in FIG. 7 and the response in the frequency domain of a rectangular window function.

FIGS. 9A and 9B are block diagrams illustrating a hardware configuration for implementing the functions of the signal processing device according to the first embodiment.

FIG. 10 is a graph showing superimposed representation of responses in the frequency domain of the sinc function, cos(2πx), −cos(4πx), and cos(6πx).

FIG. 11 is a graph showing a relationship between the frequency resolution and the peak level of sidelobes for the window function in a second embodiment and a generalized Hamming window.

FIG. 12 is a graph showing the response in the frequency domain of sinc functions that are shifted by ±½ and the response in the frequency domain of cos(πx) obtained by combining these sinc functions.

FIG. 13 is a graph showing superimposed representation of the response in the frequency domain of cos(πx) and the response in the frequency domain of cos(3πx) each included in the window function in a third embodiment.

FIG. 14 is a graph illustrating the shapes of window functions of a fourth embodiment.

FIG. 15 is a diagram illustrating frequency components of the window function in FIG. 14.

### DESCRIPTION OF EMBODIMENTS

### First Embodiment

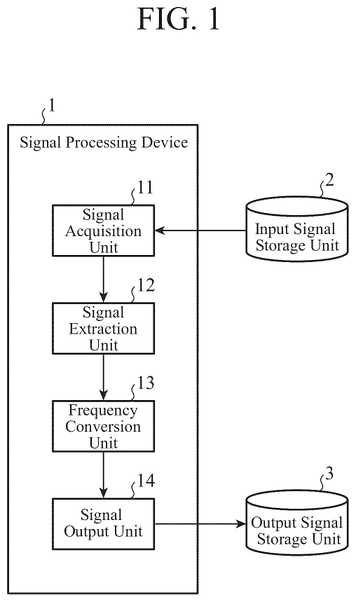

FIG. 1 is a block diagram illustrating a configuration of a signal processing device 1 according to a first embodiment. In FIG. 1, the signal processing device 1 acquires an input signal from an input signal storage unit 2, extracts a signal by multiplying the input signal by a window function, and outputs a signal obtained by performing frequency conversion on the extracted signal to an output signal storage unit 3 as an output signal. The window function includes one or a plurality of cos function terms in which at least one of the sign of a coefficient to multiply a cos function or the degree of the cos function is set in such a manner that both the frequency resolution and the reduction amount of sidelobes fall within allowable ranges.

The allowable range is a range of the frequency resolution and the reduction amount of the sidelobes that cannot be achieved by the window functions of the related art. For example, in window functions of the related art represented by a raised-cosine window, sidelobes can be reduced by adjusting a value of a positive coefficient to multiply the cos function; however, frequency resolution deteriorates depending on the reduction amount of the sidelobes.

On the other hand, since signal processing devices according to first to fourth embodiments extract a signal using the above window function or the like, both the range of the frequency resolution in the frequency domain of the signal and the range of the reduction amount of the sidelobes can be kept within the predetermined allowable range. As a result, the signal processing devices according to the first to fourth embodiments can preferably trade off between degradation of the frequency resolution and reduction of the sidelobes.

The signal processing device 1 is used, for example, in a radar system. In the radar system, the signal processing device 1 can prevent poor detection of a target attributable to sidelobes by reducing the sidelobes of a reception signal of an incoming wave from the target using the window function.

The signal processing device 1 can also be applied to a radar image generation system using a synthetic aperture radar. In this case, the signal processing device 1 can reduce noise attributable to sidelobes in a radar image by reducing the sidelobes of a reception signal.

The input signal storage unit 2 is a storage device that stores the input signal. For example, in the radar system, the input signal storage unit 2 is a storage device that temporarily stores a reception signal received by a radar device. In addition, the input signal storage unit 2 may store a signal processing program for implementing the function of the signal processing device 1. For example, a processor included in a computer executes the signal processing program read from the input signal storage unit 2, whereby the computer functions as the signal processing device 1.

The output signal storage unit 3 is a storage device that stores an output signal output from the signal processing device 1. For example, a display device (not illustrated in FIG. 1) may display display information related to the output signal stored in the output signal storage unit 3. Examples of the display information include a radar image using a synthetic aperture radar. Note that the input signal storage unit 2 and the output signal storage unit 3 may be one storage device included in the signal processing device 1 or may be separate storage devices.

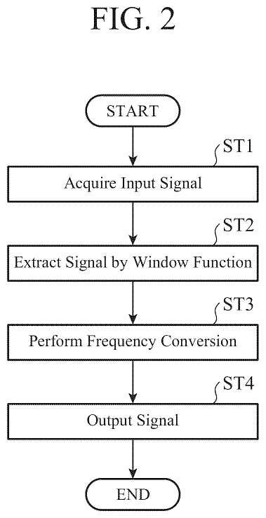

As illustrated in FIG. 1, the signal processing device 1 includes a signal acquisition unit 11, a signal extraction unit 12, a frequency conversion unit 13, and a signal output unit 14. FIG. 2 is a flowchart illustrating a signal processing method according to the first embodiment, which illustrates a signal processing method by the signal processing device 1.

Hereinafter, details of the functions of the signal acquisition unit 11, the signal extraction unit 12, the frequency conversion unit 13, and the signal output unit 14 included in the signal processing device 1 will be described with reference to FIGS. 1 and 2.

The signal acquisition unit 11 acquires an input signal that is a signal processing target (step ST1). For example, the signal acquisition unit 11 acquires the input signal stored in the input signal storage unit 2. The dimension of the input signal is not limited; however, frequency conversion is performed with respect to the dimension of t. Hereinafter, it is based on the premise that the input signal is a one-dimensional signal and is denoted as s(t).

The signal extraction unit 12 extracts a specific signal by multiplying the input signal acquired by the signal acquisition unit 11 by a window function (step ST2). The window function used by the signal extraction unit 12 includes one or a plurality of cos function terms in which at least one of the sign of a coefficient to multiply a cos function or the degree of the cos function is set in such a manner that both the frequency resolution and the reduction amount of sidelobes fall within allowable ranges. Hereinafter, it is based on the premise that the width of the signal extracted using the window function is 1. In addition, the window function is denoted as w(x), and it is hereinafter based on a premise that x is a real value in the description; however, x may be a discrete value.

Moreover, the description will be based on the premise that the design range of the window function w(x) is −0.5≤x≤0.5. Note that this design range can be modified depending on the width of a signal extracted using the window function w(x). A signal s_{w}(t) extracted by multiplying the input signal s(t) by the window function w(x) can be expressed by the following Equations (1). In the following Equations (1), to denotes the center of the width of the signal s_{w}(t) to be extracted.

$$If - 0.5 \leq t - {t}_{0} \leq 0.5 , then {s}_{w} ( t ) = w ( t - {t}_{0} ) s ( t ) . \qquad ( 1 )$$

$$In cases other than - 0.5 \leq t - {t}_{0} \leq 0.5 , then {s}_{w} ( t ) = 0$$

The frequency conversion unit 13 performs frequency conversion on the signal s_{w}(t) extracted by the signal extraction unit 12 (step ST3). For example, the frequency conversion unit 13 obtains a frequency spectrum of the signal s_{w}(t) by performing Fourier transform on the signal s_{w}(t).

In a case where frequency conversion is performed on a signal extracted using a window function of the related art, sidelobes appear in the frequency component of the signal. On the other hand, in a case where the window function of the first embodiment is used, sidelobes of the frequency component of the extracted signal are reduced. At this point, denoting a function with which frequency conversion into a frequency f is performed on the signal s_{w}(t) as Fₜ[s_{w}(t)](f), a frequency component S_{w}(f) of the signal s_{w}(t) is expressed by the following Equation (2).

$${S}_{w} ( f ) = {F}_{t} [ {s}_{w} ( t ) ] ( f ) \qquad ( 2 )$$

The signal output unit 14 outputs the signal calculated by the frequency conversion unit 13 (step ST4). For example, the signal output unit 14 outputs the frequency component S_{w}(f) to the output signal storage unit 3. As a result, a series of processing illustrated in FIG. 2 is completed. By using the window function in the first embodiment, the sidelobes of the frequency component S_{w}(f) are reduced.

The raised-cosine window of the related art will be described as an aid to understanding the window function in the first embodiment. In a case where −0.5≤x≤0.5, the raised-cosine window w_{c}(x) is expressed by a function expressed by the following Equation (3). As expressed in the following Equation (3), w_{c}(x) is represented by a linear combination of a constant term a₀ and a cosine window function whose period is adjusted. Hereinafter, k denotes an order. Note that Σ[k=1]aₖ cos(2πkx) in the following Equation (3) indicates that, in a case where M=aₖ cos(2πkx), the value of M for each degree k is added sequentially from k=1.

$${w}_{c} ( x ) = {a}_{0} + \sum [ k = 1 ] {a}_{k} cos ( 2 π kx ) {a}_{k} \geq 0 \qquad ( 3 )$$

In the raised-cosine window w_{c}(x), the generation positions (peak positions) of sidelobes in the frequency domain of the constant term a₀ and the generation positions (peak positions) of sidelobes in the frequency domain of each cos function are harmonized, and these positions are close to each other. Therefore, it is possible to effectively reduce the sidelobes by linearly combining the constant term a₀ and the cosine functions.

In a case where −0.5≤x≤0.5, the response in the frequency domain of the constant term a₀ in w_{c}(x) is given by a sinc function. In w_{c}(x), since the cos functions appropriately given the coefficients are added, sidelobes in the frequency domain of the sinc function are subtracted.

Next, the response in the frequency domain of the cos function term included in the raised-cosine window w_{c}(x) will be described. The term cos(2πkx) included in w_{c}(x) can be transformed as in the following Equation (4). Since −0.5≤x≤0.5 in this example, by performing frequency conversion of cos(2πkx), the response of cos(2πkx) in the frequency domain is expressed by a function obtained by combining two sinc functions in which shifts by ±k have occurred, as expressed in the following Equation (4).

$$cos ( 2 π k x ) = ( {e}^{j 2 π k x} + {e}^{- j 2 π k x} ) / 2 \qquad ( 4 )$$

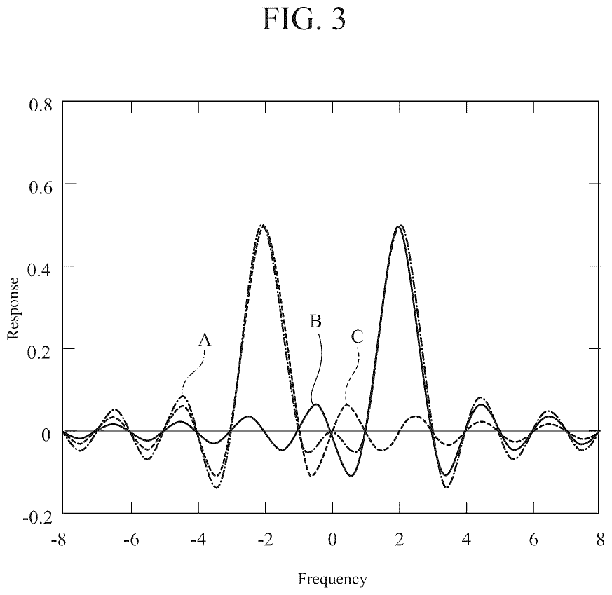

FIG. 3 is a diagram illustrating the response in the frequency domain of cos(2πkx) and the response in the frequency domain of sinc functions. In FIG. 3, k=2. Furthermore, Fₓ[cos(2πkx)](f), which is the response in the frequency domain of cos(2πkx), is indicated by a one-dot chain line A, the response in the frequency domain of sinc(f−k)/2 is indicated by a solid line B, and the response in the frequency domain of sinc(f+k)/2 has a characteristic of a broken line C. As illustrated in FIG. 3, the response of Fₓ[cos(2πkx)](f) is a function obtained by combining two sinc functions in which shifts by ±k have occurred.

Note that, in a case where k is a natural number, the null point of Fₓ[cos(2πkx)](f) overlaps with the null points of the sinc functions.

Next, a generalized Hamming window, which is a typical window function of the raised-cosine window, will be described, and the principle of the raised-cosine window will be described in detail. A generalized Hamming window wₕ(x) is expressed by the following Equation (5). The symbol α denotes a real number parameter.

$${w}_{h} ( x ) = ( 1 - α ) + α cos ( 2 π x ) \qquad ( 5 )$$

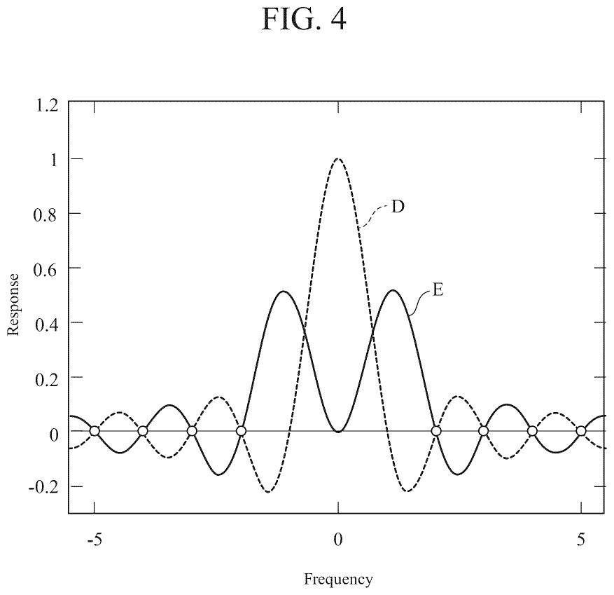

FIG. 4 is a graph showing superimposed representation of the response in the frequency domain of cos(2πx) and the response in the frequency domain of a sinc function. In FIG. 4, sinc(f), which is the response in the frequency domain of the sinc function, is indicated by a broken line D. Fₓ[cos(2πx)](f), which is the response of cos(2πx) in the frequency domain, is indicated by a solid line E.

As indicated by a hollow dot in FIG. 4, in the generalized Hamming window wₕ(x), since the null point of sinc(f) indicated by the broken line D and the null point of Fₓ[cos(2πx)](f) indicated by the solid line E coincide with each other, the generation positions of the sidelobes of the two coincide with each other. Furthermore, as illustrated in FIG. 4, the signs of the sidelobes of sinc(f) and the sidelobes of Fₓ[cos(2πx)](f) are inverted. Therefore, by superimposing sinc(f) and Fₓ[cos(2πx)](f), the sidelobes are reduced.

However, in the generalized Hamming window wₕ(x), the main lobes of Fₓ[cos(2πx)](f) are also added when sinc(f) and Fₓ[cos(2πx)](f) are superimposed, and thus the frequency resolution is deteriorated. In addition, depending on the value of α, first sidelobes of sinc(f) are excessively reduced.

A higher-order raised-cosine window w_{c}(x) further reduces sidelobes by increasing the values of individual cos function terms to be added for each order.

However, increasing the values of the cos function terms also widens the main lobes of Fₓ[cos(2πx)](f), and thus the frequency resolution is deteriorated.

Meanwhile, the window function in the first embodiment is designed to limit degradation of the frequency resolution to an allowable range and to reduce sidelobes of frequency components to fall within an allowable range. For example, the window function wₚ(x) in the first embodiment is expressed by the following Equation (6). In the following Equation (6), aₖ is a coefficient to multiply the cos function term for each degree k. Note that Σ[k=1]aₖ cos(7πkx) in the following Equation (6) indicates that, in a case where M=aₖ cos(7πkx), the value of M for each degree k is added sequentially from k=1.

$${w}_{p} ( x ) = {a}_{0} + \sum [ k = 1 ] {a}_{k} cos ( π k x ) \qquad ( 6 )$$

In the window function wₚ(x), aₖ can be a negative value. That is, the window function wₚ(x) includes a cos function term having a negative value among the cos function terms of respective degrees k. As a result, the cos function terms can be adjusted also in the negative direction.

An example of the window function wₚ(x) in the first embodiment will be described in comparison with a rectangular window function.

The window function wₚ(x) can reduce peak sidelobes of the frequency component while suppressing the deterioration in the frequency resolution as compared with rectangular window functions of the related art. For example, in the window functions of the related art, peak levels of sidelobes in the frequency domain vary; however, by using the window function wₚ(x), peak levels of sidelobes are aligned in a part of the frequency domain, and the peak levels of the sidelobes are reduced.

In a case where −0.5≤x≤0.5, the response in the frequency domain of the constant term a₀ is given by a sinc function. In a case where a window function is constituted by the constant term a₀ and the term cos(2πx) similarly to the generalized Hamming window, Fₓ[cos(2πx)](f), which is the frequency component of cos(2πx), deteriorates the frequency resolution of the sinc function.

The window function wₚ(x) in the first embodiment does not include cos(2πx) which is a cos function term having a low order that causes degradation of the frequency resolution. As a result, in the window function wₚ(x), the frequency resolution can be improved as compared with the rectangular window functions of the related art.

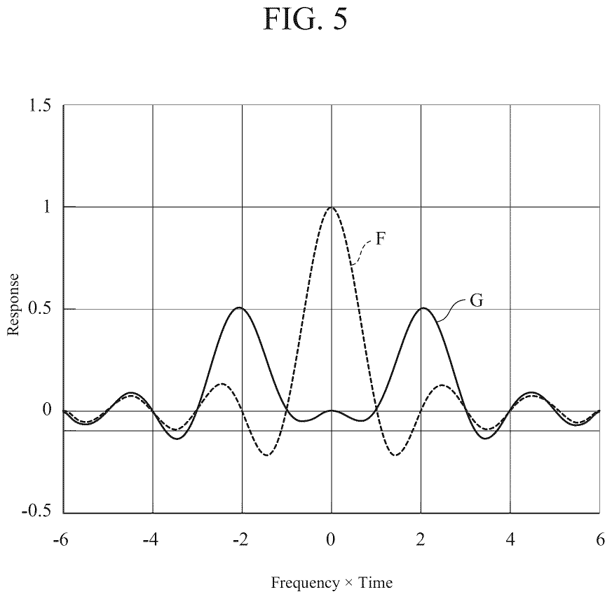

FIG. 5 is a graph showing superimposed representation of the response in the frequency domain of cos(4πx) and the response in the frequency domain of a sinc function. In FIG. 5, the response of the sinc function in the frequency domain is indicated by a broken line F, and a response Fₓ[cos(4πx)](f) of cos(4πx) in the frequency domain is indicated by a solid line G. As is clear from the broken line F and the solid line G, the main lobes of Fₓ[cos(4πx)](f) are superimposed on first sidelobes of the frequency component of the sinc function. Since the signs of the two are inverted, the first sidelobes of the sinc function are reduced.

However, the main lobes of Fₓ[cos(4πx)](f) are also superimposed on second sidelobes of the sinc function. Therefore, simply adding the term cos(4πx) disadvantageously increases the second sidelobes.

The window function wₚ(x) in the first embodiment reduces sidelobes to be reduced by superimposing the main lobes corresponding to the cos function term in the frequency domain on the sidelobes to be reduced. For example, the window function wₚ(x) also includes a term of cos(5πx). Therefore, in the window function wₚ(x), the main lobes of Fₓ[cos(5πx)](f) are used for subtraction of the sidelobes of the sinc function.

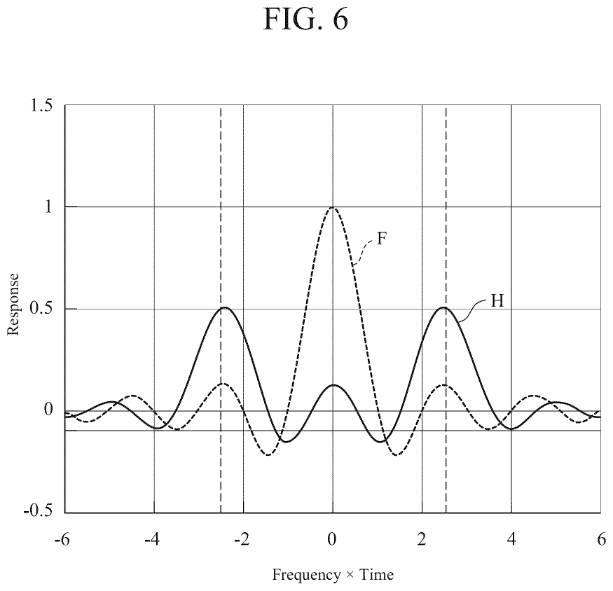

FIG. 6 is a graph showing superimposed representation of the response in the frequency domain of cos(5πx) and the response in the frequency domain of a sinc function. In FIG. 6, the response of the sinc function in the frequency domain is indicated by a broken line F, and a response Fₓ[cos(5πx)](f) of cos(5πx) in the frequency domain is indicated by a solid line H. As indicated by a broken vertical line in FIG. 6, the generation positions of the main lobes of Fₓ[cos(5πx)](f) coincide with the generation positions of second sidelobes of the sinc function. Therefore, by subtracting cos(5πx) from the constant term a₀, the second sidelobes of the sinc function can be reduced.

The window function wₚ(x) in the first embodiment may be a function expressed by the following Equation (7). In the following Equation (7), a denotes a constant term, β and γ denote coefficients, and α, β and γ>0. The window function wₚ(x) expressed in the following Equation (7) can reduce the peaks of the sidelobes with almost no degradation of the frequency resolution with respect to the sinc function.

$${w}_{p} ( x ) = α + β ( 4 π x ) - γ cos ( 5 π x ) \qquad ( 7 )$$

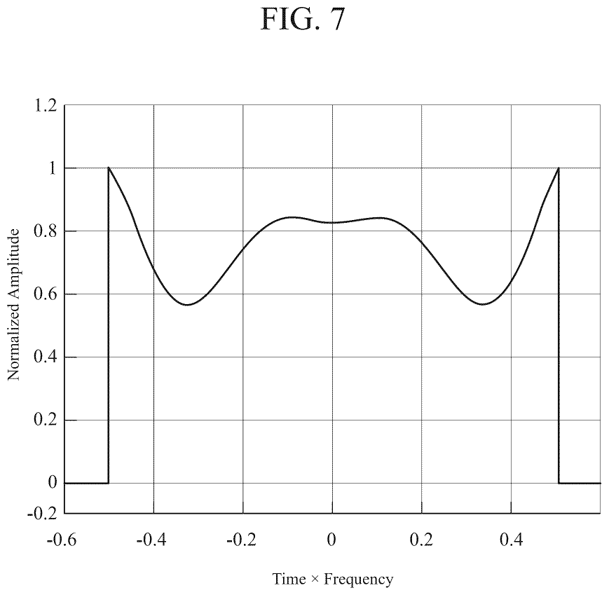

FIG. 7 is a graph illustrating the shape of the window function in the first embodiment and illustrates the window function wₚ(x) expressed by the above Equation (7). As illustrated in FIG. 7, in the characteristic shape of the window function wₚ(x), both end portions protrude, and a central portion is recessed as compared with both end portions. By adjusting the window function wₚ(x) having the characteristic shape illustrated in FIG. 7, the frequency resolution can be improved to fall within an allowable range, and furthermore, the peak levels of the side lobes can be also reduced to fall within an allowable range.

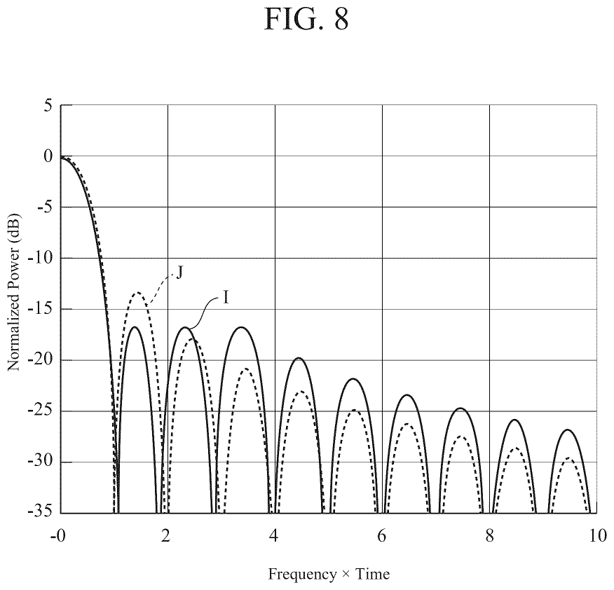

FIG. 8 is a graph showing superimposed representation of the response in the frequency domain of the window function wₚ(x) in FIG. 7 and the response in the frequency domain of a window function of the related art having a rectangular characteristic shape. In FIG. 8, the response in the frequency domain of the window function wₚ(x) is indicated by a solid line I, and the response in the frequency domain of the rectangular window function is indicated by a broken line J. As is clear from the solid line I and the broken line J, in the response in the frequency domain of the window function wₚ(x) indicated by the solid line I, peak levels of sidelobes are reduced while the frequency resolution is hardly deteriorated, with respect to the sinc function, as compared with the window function of the related art indicated by the broken line J. Furthermore, in the response in the frequency domain of the window function wₚ(x), first, second, and third side lobes are aligned to approximately the same level, and the peak levels thereof are reduced.

The window function wₚ(x) in the first embodiment may be obtained by improving the Hann window.

A Hann window wₕₐₙ(x) is a window function of the related art given by the following Equation (8). As expressed in the following Equation (8), in the Hann window wₕₐₙ(x), a constant term and a term of cos(2πx) are added with equal gain, so that the attenuation rate of sidelobes in the frequency direction is high. The Hann window wₕₐₙ(x) exhibits an excellent effect of attenuating the sidelobes in the frequency direction but has a problem that first sidelobes of a sinc function are relatively high.

$${w}_{han} ( x ) = \{ 1 + cos ( 2 π x ) \} / 2 \qquad ( 8 )$$

The window function wₚ(x) in the first embodiment reduces the peak power of the sidelobes without deteriorating the attenuation rate of sidelobes in the frequency direction. For example, this is expressed by the following Equation (9). In the following Equation (9), α and β are real numbers, and α and β>0.

$${w}_{p} ( x ) = ( 1 - α + β ) \{ 1 + cos ( 2 π x ) \} / 2 + α \{ cos ( 4 π x ) + cos ( 6 π x ) \} / 2 - β \{ cos ( 6 π x ) + cos ( 8 π x ) \} / 2 \qquad ( 9 )$$

The window function wₚ(x) illustrated in the above Equation (9) reduces the first sidelobes of the Hann window, which are expressed by {1+cos(2πx)}/2, by the main lobes of the term of (cos(4πx)+cos(6πx))/2 and reduces second sidelobes of the Hann window by the main lobes of the term of −{cos(6πx)+cos(8πx)}/2. As a result, in the window function wₚ(x) expressed by the above Equation (9), levels of sidelobes that have varied are partially aligned without sacrificing the attenuation rate of the sidelobes, and, at the same time, the peak power of the sidelobes can be reduced.

Since the window function wₚ(x) expressed in the above Equation (9) does not include the term of {cos(2πx)+cos(4πx)}/2, the peak power of the sidelobes can be reduced without excessively deteriorating the frequency resolution as compared with the Hann window.

Note that the window function wₚ(x) expressed in the above Equation (9) can be generalized as in the following Equation (10) by setting the constant term a₀>0.

Σ[k=0](−1)^{k}aₖ[{cos(2kπx)+cos(2(k+1)πx)}/2] in the following Equation (10) indicates that, in a case where M=(−1)^{k}aₖ[{cos(2kπx)+cos(2(k+1)πx)}/2]), the value of M for each degree k is added sequentially from k=1.

$${w}_{p} ( x ) = \sum [ k = 0 ] {( - 1 )}^{k} {a}_{k} [ \{ cos ( 2 k π x ) + cos ( 2 ( k + 1 ) π x ) \} / 2 ] \qquad ( 10 )$$

In addition, as a window function of the related art that is excellent in sidelobe attenuation, there is a window function expressed by the following Equation (11).

$${w}_{p} ( x ) = 0.75 cos ( π x ) + 0.25 cos ( 3 π x ) \qquad ( 11 )$$

The window function wₚ(x) in the first embodiment may be obtained by improving the window function of the related art expressed by the above Equation (11). For example, a window function wₚ(x) expressed by the following Equation (12) is obtained by introducing a coefficient aₖ into the above Equation (11).

Note that the window function wₚ(x) expressed by the following Equation (12) can reduce sidelobes by a similar principle to that of the window function wₚ(x) expressed by the above Equation (9). In the following Equation (12), Σ[k=1](−1)^{k-1}aₖ indicates that, in a case where M1=(−1)^{k-1}aₖ, the value of M1 for each degree k is added sequentially from k=1. Furthermore, Σ[k=1](−1)^{k-1}aₖFₖ(x) indicates that, in a case where M2=(−1)^{k-1}aₖFₖ(x), the value of M2 for each degree k is added sequentially from k=1.

$${w}_{p} ( x ) = ( 1 - Σ [ k = 1 ] {( - 1 )}^{k - 1} {a}_{k} ) \{ 0.75 cos ( π x ) + 0.25 cos ( 3 π x ) \} + Σ [ k = 1 ] {( - 1 )}^{k - 1} {a}_{k} {F}_{k} ( x ) \qquad ( 12 )$$

The function Fₖ(x) in the above Equation (12) is expressed by the following Equation (13).

$${F}_{k} ( x ) = [ 0.125 cos \{ ( 2 k + 1 ) π x \} + 0.3 \; 75 cos \{ ( 2 k + 3 ) π x \} ] + 0.3 \; 75 cos [ \{ ( 2 k + 5 ) π x \} + 0.1 \; 25 cos \{ ( 2 k + 7 ) π x \} ] \qquad ( 13 )$$

As described above, the window function wₚ(x) in the first embodiment focuses on the correspondence relationship between the main lobes of the frequency component of the cos function term and the sidelobes of the frequency component of the sinc function representing the constant term and reduces the sidelobes while suppressing degradation of the frequency resolution. For example, by using the signal processing device 1 in a radar system, the signal processing device 1 can reduce lower-order sidelobes superimposed on a reception signal from a target by multiplying the reception signal from the target by the window function, and thus it is possible to reduce the probability that the target may not be detected due to lower-order sidelobes. In addition, by using the signal processing device 1 in a synthetic aperture radar, the signal processing device 1 can reduce low-order sidelobes by multiplying a radar signal by the window function, and thus noise due to the low-order sidelobes in a radar image can be made more inconspicuous.

Next, a hardware configuration for implementing the functions of the signal processing device 1 will be described.

The functions of the signal acquisition unit 11, the signal extraction unit 12, the frequency conversion unit 13, and the signal output unit 14 included in the signal processing device 1 are implemented by a processing circuit. That is, the signal processing device 1 includes a processing circuit for executing the processing from step ST1 to step ST4 illustrated in FIG. 2. The processing circuit may be dedicated hardware or a central processing unit (CPU) for executing a program stored in a memory.

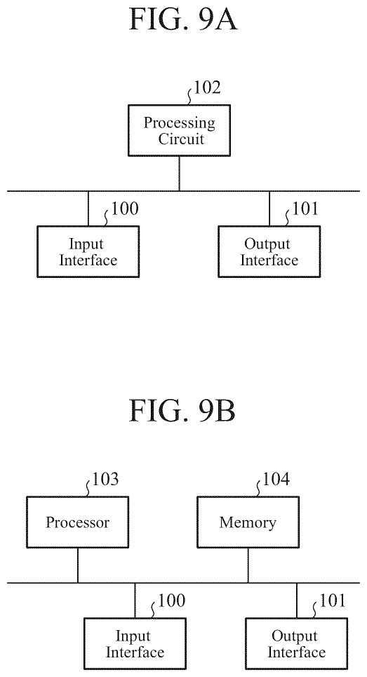

FIG. 9A is a block diagram illustrating a hardware configuration for implementing the functions of the signal processing device 1. FIG. 9B is a block diagram illustrating a hardware configuration for executing the software that implements the functions of the signal processing device 1. In FIGS. 9A and 9B, an input interface 100 relays an input signal acquired by the signal processing device 1 from the input signal storage unit 2. An output interface 101 relays an output signal output from the signal processing device 1 to the output signal storage unit 3.

In a case where the processing circuit is a processing circuit 102 of dedicated hardware illustrated in FIG. 9A, the processing circuit 102 may be a single circuit, a composite circuit, a programmed processor, a parallel programmed processor, an application specific integrated circuit (ASIC), a field-programmable gate array (FPGA), or a combination thereof, for example. The functions of the signal acquisition unit 11, the signal extraction unit 12, the frequency conversion unit 13, and the signal output unit 14 included in the signal processing device 1 may be implemented by separate processing circuits, or these functions may be collectively implemented by one processing circuit.

In a case where the processing circuit is a processor 103 illustrated in FIG. 9B, the functions of the signal acquisition unit 11, the signal extraction unit 12, the frequency conversion unit 13, and the signal output unit 14 included in the signal processing device 1 are implemented by software, firmware, or a combination of software and firmware. Note that the software or the firmware is described as a program and is stored in a memory 104.

The processor 103 reads and executes the program stored in the memory 104 to implement the functions of the signal acquisition unit 11, the signal extraction unit 12, the frequency conversion unit 13, and the signal output unit 14 included in the signal processing device 1. For example, the signal processing device 1 includes the memory 104 for storing programs execution of which by the processor 103 results in execution of processes of steps ST1 to ST4 illustrated in FIG. 2. These programs cause a computer to execute procedures or methods performed by the processing performed by the signal acquisition unit 11, the signal extraction unit 12, the frequency conversion unit 13, and the signal output unit 14. The memory 104 may be a computer-readable storage medium storing the programs for causing a computer to function as the signal acquisition unit 11, the signal extraction unit 12, the frequency conversion unit 13, and the signal output unit 14.

The memory 104 corresponds to a nonvolatile or volatile semiconductor memory such as a random access memory (RAM), a read only memory (ROM), a flash memory, an erasable programmable read only memory (EPROM), or an electrically-EPROM (EEPROM) (registered trademark), a magnetic disc, a flexible disc, an optical disc, a compact disc, a mini disc, a DVD, or the like.

A part of the functions of the signal acquisition unit 11, the signal extraction unit 12, the frequency conversion unit 13, and the signal output unit 14 included in the signal processing device 1 may be implemented by dedicated hardware, and another part thereof may be implemented by software or firmware. For example, the functions of the signal acquisition unit 11 and the signal output unit 14 are implemented by the processing circuit 102 that is dedicated hardware, and the functions of the signal extraction unit 12 and the frequency conversion unit 13 are implemented by the processor 103 reading and executing a program stored in the memory 104. In this manner, the processing circuit can implement the functions described above by hardware, software, firmware, or a combination thereof.

As described above, the signal processing device 1 according to the first embodiment includes the signal acquisition unit 11 that acquires the input signal s(t), the signal extraction unit 12 that extracts the specific signal s_{w}(t) by multiplying the input signal s(t) by the window function wₚ(x), the frequency conversion unit 13 that performs frequency conversion on the extracted signal s_{w}(t), and the signal output unit 14 that outputs the frequency-converted signal s_{w}(f). The window function wₚ(x) includes one or a plurality of cos function terms in which at least one of the sign of the coefficient to multiply the cos function or the degree of the cos function is set in such a manner that both the frequency resolution and the reduction amount of sidelobes fall within allowable ranges. The signal processing device 1 can adjust the cos function terms also in the negative direction by using the window function. As a result, the signal processing device 1 can preferably trade-off the frequency resolution and sidelobe characteristics than a case of using a window function of the related art, which is represented by the raised-cosine window. Note that similar effects can be obtained also in the signal processing method illustrated in FIG. 2 executed by the signal processing device 1.

In the signal processing device 1 according to the first embodiment, the window function wₚ(x) does not include a low-order cos function term that causes degradation of the frequency resolution. As a result, in the window function wₚ(x), the degradation of the frequency resolution is smaller as compared with that by the rectangular window function of the related art, and the sidelobes of the frequency component of the sinc function can be reduced.

In the signal processing device 1 according to the first embodiment, the window function wₚ(x) reduces sidelobes to be reduced by superimposing the main lobes corresponding to the cos function term in the frequency domain on the sidelobes to be reduced. As a result, the window function wₚ(x) can reduce the sidelobes of the frequency component of the sinc function. For example, since the window function wₚ(x) includes a term of cos(kπx), the sidelobes are reduced by superimposing the main lobes of Fₓ[cos(kπx)](f) in the frequency domain on the sidelobes. Note that the window function wₚ(x) may include a term obtained by extending a window function such as the Hann window.

In the signal processing device 1 according to the first embodiment, the window function wₚ(x) has a characteristic shape in which the central portion is recessed as compared with both end portions. As a result, the window function wₚ(x) can improve the frequency resolution as compared with that by a window function of the related art having a rectangular characteristic shape.

### Second Embodiment

A window function in a second embodiment further includes a term of cos(kπx) in addition to the function of the generalized Hamming window, whereby sidelobes of the frequency component can be reduced while suppressing degradation of the frequency resolution to be small. For example, specifically, the window function in the second embodiment is obtained by adding a term of −cos(4πx) and a term of cos(6πx) to the function of the generalized Hamming window.

Similarly to the first embodiment, a signal processing device 1 according to the second embodiment includes a signal acquisition unit 11 that acquires an input signal s(t), a signal extraction unit 12 that extracts a specific signal s_{w}(t) by multiplying the input signal s(t) by a window function wₚ(x), a frequency conversion unit 13 that performs frequency conversion on the extracted signal s_{w}(t), and a signal output unit 14 that outputs the frequency-converted signal s_{w}(f). As described above, the window function wₚ(x) includes a cos function term having a negative value.

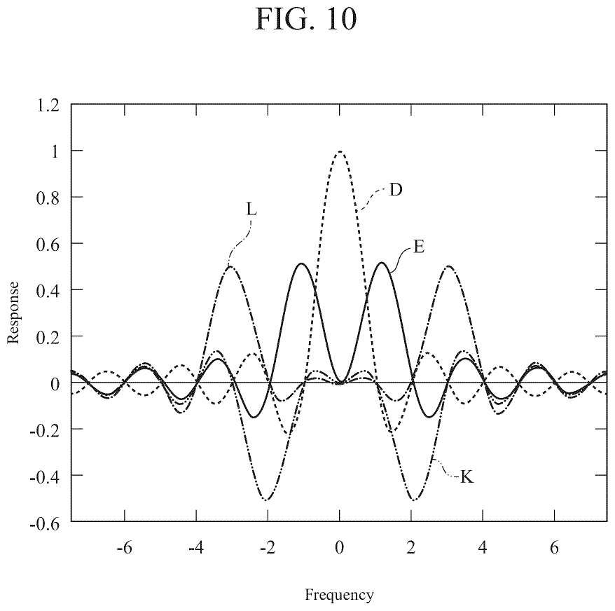

FIG. 10 is a graph showing superimposed representation of responses in the frequency domain of a sinc function, cos(2πx), −cos(4πx), and cos(6πx). In FIG. 10, sinc(f), which is the response in the frequency domain of the sinc function, is indicated by a broken line D, and Fₓ[cos(2πx)](f), which is the response in the frequency domain of cos(2πx), is indicated by a solid line E. Furthermore, Fₓ[−cos(4πx)](f), which is the response in the frequency domain of −cos(4πx), is indicated by a two-dot chain line K, and Fₓ[cos(6πx)](f), which is the response in the frequency domain of cos(6πx), is indicated by a one-dot chain line L.

As illustrated in FIG. 10, sidelobes away from the main lobes in each response in the frequency domain of cos(2πx), −cos(4πx), and cos(6πx) are inverted in sign from sidelobes in the response of the frequency domain of the sinc function. Unlike the generalized Hamming window including only the constant term and cos(2πx), the window function in the second embodiment includes the terms of −cos(4πx) and cos(6πx), whereby the sidelobes of the frequency component can be further reduced.

Note that the main lobes of Fₓ[−cos(4πx)](f) excessively increase first sidelobes in sinc(f) but excessively decrease second sidelobes.

Furthermore, the main lobes of Fₓ[cos(6πx)](f) excessively increase the second sidelobes in sinc(f) but excessively decrease third sidelobes.

In the generalized Hamming window, depending on the value of α, the main lobes of Fₓ[cos(2πx)](f) excessively decrease the first sidelobes in sinc(f).

In consideration of these, in the window function in the second embodiment, the value of the term −cos(4πx) is determined depending on the reduction amount of the first sidelobes of sinc(f) reduced by the main lobes of F[cos(2πx)](f), and the second sidelobes in sinc(f) are reduced by the main lobes of Fₓ[−cos(4πx)](f). Furthermore, the value of the term cos(6πx) is determined depending on the reduction amount of the second sidelobes of sinc(f) reduced by the main lobes of Fₓ[−cos(4πx)](f).

In the window function in the second embodiment, each of the values of a coefficient that multiplies the term of −cos(4πx) and a coefficient that multiplies cos(6πx) is small, and thus degradation of the frequency resolution attributable to these terms is small. Furthermore, the window function in the second embodiment can align the levels of sidelobes in the frequency domain and reduce the levels of the sidelobes as a whole. Therefore, in the window function in the second embodiment, degradation of the frequency resolution is smaller as compared with that by the generalized Hamming window, whereby the sidelobes in the frequency domain can be reduced.

The window function wₚ(x) in the second embodiment is expressed by, for example, the following Equation (14). In the following Equation (14), α, β, and γ are real numbers, and α, β, and γ>0.

The symbol α is similar to α in the generalized Hamming window.

The symbol β is set depending on the reduction amount of the first sidelobes by the main lobes of Fₓ[cos(2πx)](f). The symbol γ is set depending on the reduction amount of the second sidelobes of sinc(f) reduced by the main lobes of Fₓ[−cos(4πx)](f).

$${w}_{p} ( x ) = ( 1 - α ) + α cos ( 2 π x ) - β cos ( 4 π x ) + γ cos ( 6 π x ) \qquad ( 14 )$$

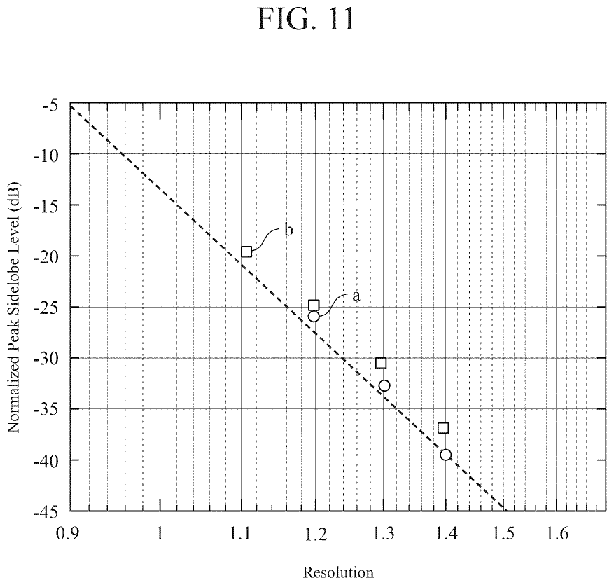

FIG. 11 is a graph showing a relationship between the frequency resolution and the peak level of sidelobes for the window function in the second embodiment and a generalized Hamming window. The horizontal axis in FIG. 11 represents an index of the frequency resolution obtained by normalizing a width of 3 dB of a power profile of the frequency component with the width of 3 dB in a rectangular window. The vertical axis in FIG. 11 represents the normalized peak sidelobe level. The relationship of the window function in the second embodiment is indicated by hollow dots, and the relationship of the generalized Hamming window is indicated by hollow squares. As illustrated in FIG. 11, in the window function according to the second embodiment, the peak sidelobe levels are reduced as compared with those of the generalized Hamming window.

For example, with a radar system including the signal processing device 1 using the window function wₚ(x) of the second embodiment, the signal processing device 1 can reduce lower-order sidelobes superimposed on a reception signal from a target by multiplying the reception signal from the target by the window function, and thus it is possible to reduce the probability that the target may not be detected due to lower-order sidelobes. In addition, by applying the signal processing device 1 in a synthetic aperture radar, the signal processing device 1 can reduce low-order sidelobes by multiplying a radar signal by the window function, and thus noise due to the low-order sidelobes in a radar image can be made more inconspicuous.

Note that the window function wₚ(x) expressed in the above Equation (14) can be generalized as in the following Equation (15) by setting the constant term a₀≥0. A term Σ[k=0](−1)^{k-1}aₖ cos(2kπx) in the following Equation (15) indicates that, in a case where M=(−1)^{k-1}aₖ cos(2kπx), the value of M for each degree k is added sequentially from k=1.

$${w}_{p} ( x ) = {a}_{0} + Σ [ k = 1 ] {( - 1 )}^{k - 1} {a}_{k} cos ( 2 k π x ) \qquad ( 15 )$$

As described above, the signal processing device 1 according to the second embodiment includes the signal acquisition unit 11 that acquires the input signal s(t), the signal extraction unit 12 that extracts the specific signal s_{w}(t) by multiplying the input signal s(t) by the window function wₚ(x), the frequency conversion unit 13 that performs frequency conversion on the extracted signal s_{w}(t), and the signal output unit 14 that outputs the frequency-converted signal s_{w}(f). The window function wₚ(x) includes a cos function term in which the sign of a coefficient to multiply the cos function is set in such a manner that both the frequency resolution and the reduction amount of sidelobes fall within allowable ranges. The signal processing device 1 can adjust the cos function terms also in the negative direction by using the window function. As a result, the signal processing device 1 can preferably trade-off the frequency resolution and sidelobe characteristics than a case of using a window function of the related art, which is represented by the raised-cosine window.

In the signal processing device 1 according to the second embodiment, the window function wₚ(x) determines cos(2πx), −cos(4πx), and cos(6πx), which are cos function terms of respective degrees k, depending on the reduction amount of the sidelobes in the frequency domain. As a result, the window function wₚ(x) can reduce sidelobes of the frequency component of the generalized Hamming window with almost no degradation in the frequency resolution.

### Third Embodiment

A window function in a third embodiment does not include any constant term but includes a cos function term and can reduce sidelobes in the frequency domain. In particular, the performance of the window function in the third embodiment is in the middle between that of the generalized Hamming window and that of the Blackman window of the related art and enables trade-off between the frequency resolution and sidelobe characteristics more preferably than these window functions.

Similarly to the first embodiment, a signal processing device 1 according to the third embodiment includes a signal acquisition unit 11 that acquires an input signal s(t), a signal extraction unit 12 that extracts a specific signal s_{w}(t) by multiplying the input signal s(t) by a window function wₚ(x), a frequency conversion unit 13 that performs frequency conversion on the extracted signal s_{w}(t), and a signal output unit 14 that outputs the frequency-converted signal s_{w}(f).

First, the Blackman window of the related art will be described to assist understanding of the window function in the third embodiment. The generalized Hamming window described above has an advantage that the characteristics can be designed by a single parameter α. Meanwhile, although the Blackman window has a lower frequency resolution than that of the generalized Hamming window, characteristics can be designed with a single parameter similarly to the generalized Hamming window. The Blackman window is expressed by the following Equation (16). For example, a Blackman window with α=0.08 is well known. This Blackman window has a lower frequency resolution than the generalized Hamming window but can reduce sidelobes.

$${w}_{b} = ( 0.5 - α ) + 0.5 cos ( 2 π x ) + α cos ( 4 π x ) \qquad ( 16 )$$

The window function in the third embodiment can design characteristics by a single parameter α by using a half-cycle sine window, and the performance thereof is in the middle between those of the generalized Hamming window and the Blackman window. In a case where −0.5≤x≤0.5, the half-cycle sine window can be expressed by the following Equation (17).

$${w}_{S} ( x ) = cos ( π x ) \qquad ( 17 )$$

The frequency characteristic of the window function given by cos(πx) is obtained by adding the two sinc functions shifted in terms of frequency, and sidelobes in the frequency domain are reduced.

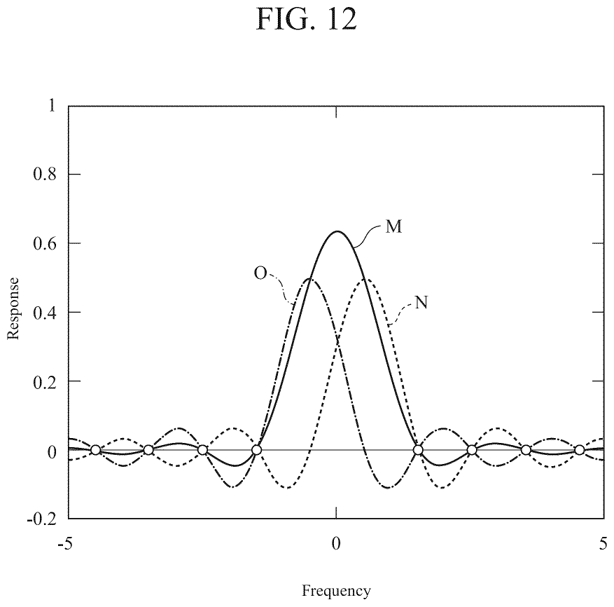

FIG. 12 is a graph showing the response in the frequency domain of sinc functions that are shifted by ±½ and the response in the frequency domain of cos(πx) obtained by combining these sinc functions. In FIG. 12, Fₓ[cos(πx)](f), which is the response of cos(πx) in the frequency domain, is indicated by a solid line M. In addition, sinc(f−0.5)/2, which is the response in the frequency domain of the sinc function shifted by −½, is indicated by a broken line N, and sinc(f+0.5)/2, which is the response in the frequency domain of the sinc function shifted by +½, is indicated by an alternate long and short dash line O.

As is apparent from the solid line M, the broken line N, and the alternate long and short dash line O, Fₓ[cos(πx)](f) is equal to a combination of sinc(f−0.5)/2 and sinc(f+0.5)/2. Furthermore, as indicated by hollow dots in FIG. 12, null points of sinc(f−0.5)/2 and sinc(f+0.5)/2 coincide with each other, and the signs of overlapping sidelobes are inverted from each other. Therefore, sidelobes are reduced in Fₓ[cos(πx)](f) obtained by combining sinc(f−0.5)/2 and sinc(f+0.5)/2. As described above, since the half-cycle sine window corresponds to a combination of the two sinc functions that are frequency-shifted, it is possible to preferably reduce sidelobes although the frequency resolution is low.

By using cos(πx), the window function in the third embodiment can trade-off between the frequency resolution and sidelobe characteristics in a region where neither the generalized Hamming window nor the Blackman window can achieve the same. In a case where 1 is a natural number, null points of cos{(21+1)πx} coincides with null points of Fₓ[cos(πx)](f) which is the response in the frequency domain of cos(πx).

The window function in the third embodiment includes a term of cos(3πx) expressed by cos{(21+1) πx} and the term of cos(πx) which is the half-cycle sine window.

By setting a setting parameter α to α>0, the window function in the third embodiment can be expressed by the following Equation (18).

$${w}_{p} ( x ) = ( 1 - α ) cos ( π x ) + α cos ( 3 π x ) \qquad ( 18 )$$

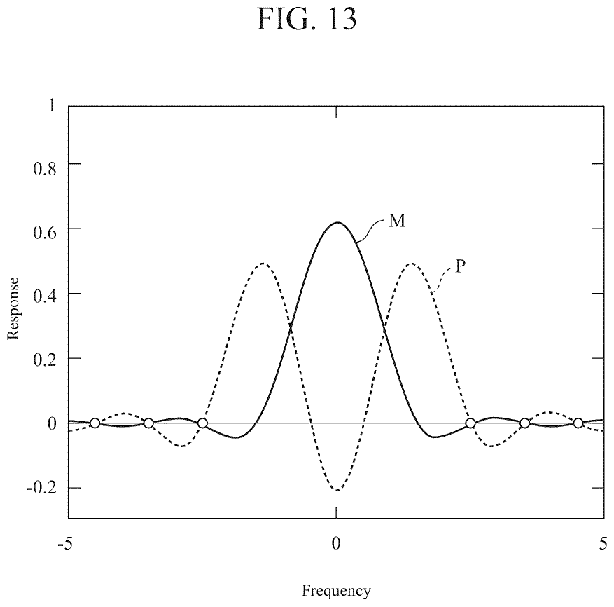

FIG. 13 is a graph showing superimposed representation of the response in the frequency domain of cos(πx) and the response in the frequency domain of cos(3πx) each included in the window function in the third embodiment. In FIG. 13, Fₓ[cos(πx)](f) that is the response in the frequency domain of cos(πx) is indicated by a solid line M, and Fₓ[cos(3πx)](f) that is the response in the frequency domain of cos(3πx) is indicated by a broken line P. As is clear from the solid line M and the broken line P, the generation positions of sidelobes of Fₓ[cos(πx)](f) and the generation positions of sidelobes of Fₓ[cos(3πx)](f) are harmonized, and the signs of the two are inverted. Therefore, since the term of cos(πx) and the term of cos(3πx) are added in the window function in the third embodiment, the sidelobes of the frequency component are reduced.

That is, in the window function according to the third embodiment, in addition to cos(πx) which is the half-cycle sine window from which favorable sidelobe characteristics can be obtained, further favorable sidelobe characteristics can be obtained by using the term of cos(3πx). The window function in the third embodiment can be designed by a single parameter similarly to the generalized Hamming window and the Blackman window.

In addition, the window function wₚ(x) in the third embodiment can improve performance as in the following Equation (19) by incorporating the design concept of the window function described in the second embodiment, setting coefficients to multiply the cos function terms to α, β, and γ, and setting α, β, and γ>0. The window function wₚ(x) given by the following Equation (19) is similar to the above Equation (14) described in the second embodiment.

$${w}_{p} ( x ) = ( 1 - α ) cos ( π x ) + α cos ( 3 π x ) - β cos ( 5 π x ) + γ cos ( 7 π x ) \qquad ( 19 )$$

Note that the window function wₚ(x) expressed in the above Equation (19) can be generalized as in the following Equation (20) by setting the constant term a₀≥0. Σ[k=0](−1)^{k-1}aₖ cos{(2k+1)πx} in the following Equation (20) indicates that, in a case where M=(−1)^{k-1}aₖ cos{(2k+1)πx}, the value of M for each degree k is added sequentially from k=1.

$${w}_{p} ( x ) = {a}_{0} cos ( π x ) + Σ [ k = 1 ] {( - 1 )}^{k - 1} {a}_{k} cos \{ ( 2 k + 1 ) π x \} \qquad ( 20 )$$

In the signal processing device 1 according to the third embodiment, the window function wₚ(x) does not include the constant term a₀ but is constituted by cos function terms. The signal processing device 1 according to the third embodiment can preferably trade-off between the frequency resolution and the sidelobe characteristics by using the window function wₚ(x). For example, with the window function wₚ(x) including cos(3πx) in addition to cos(πx) which is the half-cycle sine window, it is possible to make the performance thereof to be in the middle between those of the generalized Hamming window and the Blackman window and to preferably trade-off between the frequency resolution and sidelobe characteristics than the window functions of the related art can.

### Fourth Embodiment

A window function in the fourth embodiment has a characteristic shape in which a central portion is recessed as compared with both end portions. In the window function in the fourth embodiment, discontinuity at both end portions, which are boundaries between the inside and the outside of the window, is emphasized, and for example, the depth of recess in the central portion can be adjusted depending on the value of the coefficient α. Since the depth of recess in the central portion of the window function affects the width of the main lobes in the frequency domain, it is possible to improve the frequency resolution by appropriately adjusting the value of the coefficient α.

Similarly to the first embodiment, a signal processing device 1 according to the fourth embodiment includes a signal acquisition unit 11 that acquires an input signal s(t), a signal extraction unit 12 that extracts a specific signal s_{w}(t) by multiplying the input signal s(t) by a window function wₚ(x), a frequency conversion unit 13 that performs frequency conversion on the extracted signal s_{w}(t), and a signal output unit 14 that outputs the frequency-converted signal s_{w}(f). As described above, the window function wₚ(x) includes a cos function term having a negative value.

A window function of the related art is generally designed to reduce sidelobes in the frequency domain by emphasizing the continuity at both end portions that are boundaries between the inside and the outside of the window.

Meanwhile, the window function in the fourth embodiment has a characteristic shape in which the central portion is recessed as compared with both end portions, and discontinuity at both end portions is emphasized. With this shape, deterioration of the frequency resolution can be suppressed. The window function wₚ(x) in the third embodiment can be expressed by the following Equation (21) by setting the coefficient α>0.

$${w}_{p} ( x ) = 1 - α cos ( π x ) \qquad ( 21 )$$

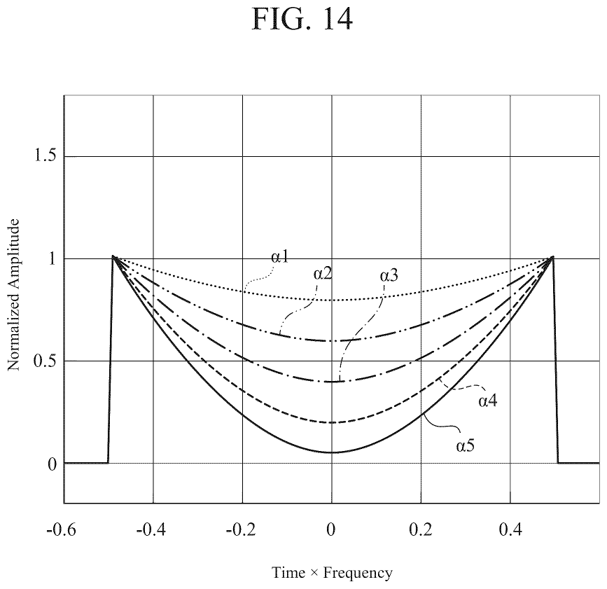

FIG. 14 is a graph illustrating the shape of the window function wₚ(x) in the fourth embodiment and illustrates window functions wₚ(x) corresponding to respective coefficients of α1, α2, α3, α4, and α5. In FIG. 14, α1=0.2, α2=0.4, α3=0.6, α4=0.8, and α5=0.95. In the shape of the window function wₚ(x), as the value of the coefficient α is increased from α1 to α5, the recess in the central portion is deeper, and as the recess in the central portion is deeper, the level of protrusion of both end portions also is steeper, and the discontinuity is emphasized.

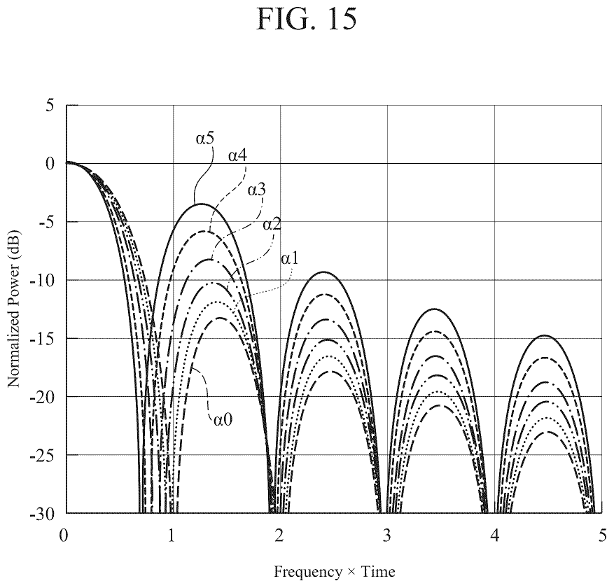

FIG. 15 is a diagram illustrating the frequency component of the window function wₚ(x) of FIG. 14 and illustrates the window functions wₚ(x) corresponding to the respective coefficients of α0, α1, α2, α3, α4, and α5. In FIG. 15, α0=0, α1=0.2, α2=0.4, α3=0.6, α4=0.8, and α5=0.95. In the frequency component of the window function wₚ(x), sidelobes increase as the value of the coefficient α increases, whereas the width of the main lobes is narrowed, and thus the frequency resolution is improved. For example, by appropriately setting the value of the coefficient α depending on the application of the window function, the signal processing device 1 according to the third embodiment can improve the frequency resolution more than a window function of the related art can.

Note that the window function wₚ(x) in the fourth embodiment only needs to have a characteristic shape in which the central portion is recessed as compared with both end portions, and components of the function that implements this shape are not limited to those described above. In addition, in the window function wₚ(x) in the fourth embodiment, it is also possible to design parameters in such a manner that the frequency resolution and the reduction amount of the sidelobes fall within allowable ranges.

In addition, the window function wₚ(x) in the fourth embodiment can also be expressed as the following Equation (22) by setting coefficients to multiply the cos function terms to α, β, and γ and setting α, β, and γ>0 by adopting the design concept of the window function described in the first embodiment. As described in the first embodiment, the window function wₚ(x) of the following Equation (22) reduces the sidelobes by the main lobes of the frequency component of cos(kπx).

$${w}_{p} ( x ) = 1 - α cos ( π x ) + β cos ( 3 π x ) - γ cos ( 5 π x ) \qquad ( 22 )$$

Note that the window function wₚ(x) expressed in the above Equation (22) can be generalized as in the following Equation (23) by setting the constant term a₀≥0. Σ[k=0](−1)^{k}aₖ cos{(2k−1)πx} in the following Equation (23) indicates that, in a case where M=(−1)^{k}aₖ cos{(2k−1)πx}, the value of M for each degree k is added sequentially from k=1.

$${w}_{p} ( x ) = {a}_{0} + Σ [ k = 1 ] {( - 1 )}^{k} {a}_{k} cos \{ ( 2 k - 1 ) π x \} \qquad ( 23 )$$

Next, use examples of the window functions described in the first to fourth embodiments will be described.

Reference Literature 1 below describes an example of a synthetic aperture radar image (hereinafter, referred to as an SAR image) using multi-apodization. The multi-apodization is a method for reducing sidelobes without degradation of the frequency resolution by extracting a signal having the minimum intensity from among signals having been subjected to processing using no window function or signals having been subjected to processing using a plurality of window functions.

For example, the signal extraction unit 12 multiplies the window function wₚ(x) and extracts a signal from the input signal. The frequency conversion unit 13 performs frequency conversion on the signal extracted by the signal extraction unit 12. The signal output unit 14 extracts a signal having the minimum intensity from the signal having been subjected to the frequency conversion by the frequency conversion unit 13 and outputs the signal.

In addition to the processing result using the window function wₚ(x), an output signal may be extracted from a processing result not using the window function wₚ(x). For example, out of a signal obtained by frequency-converting a signal extracted from the input signal having been multiplied by the window function wₚ(x) and a signal obtained by frequency-converting the input signal, the signal output unit 14 may extract a signal having the minimum strength.

As described above, by using the window function wₚ(x) in the fourth embodiment as a window function in multi-apodization, it is possible to reduce sidelobes while improving the frequency resolution.
(Reference Literature 1) H. C. Stankwitz, R. J. Dallaire, and J. R. Fienup, “Nonlinear apodization for sidelobe control in SAR imagery,” IEEE Trans. Aerosp. Electron. Syst., vol. 31, no. 1, pp. 267-279, January 1995.

In addition, in the signal processing device 1, a finite impulse response filter (hereinafter, referred to as an FIR filter) can substitute for the processing of the window function. For example, the frequency conversion unit 13 performs frequency conversion on the input signal s(t) to generate a signal S(f). The signal output unit 14 extracts a frequency-converted specific signal S_{w}(f) from the frequency-converted input signal S(f) using the FIR filter set in such a manner that both the frequency resolution and the reduction amount of the sidelobes fall within the allowable ranges. The FIR filtering is expressed by the following Equation (24) as S(f)=Fₜ[s(t)](f). In the following Equation (24), FIR filtering gives a weight w to each of signals shifted by ±Δf. A symbol Δf denotes one frequency bin when performing Nyquist sampling to digitally process a signal. In a case where the signal shifted by Δf corresponds to one sample, the weight w is given to signals shifted by ±1 sample.

$${S}_{w} ( f ) = S ( f ) + wS ( f + Δ f ) + wS ( f + Δ f ) \qquad ( 24 )$$

Reference Literature 1 shows FIR filtering in which a weight w, which is a real number, is 0<w≤0.5 only for the purpose of reducing sidelobes.

Meanwhile, the signal processing device 1 according to the first embodiment can improve the frequency resolution similarly to the case of multiplying the input signal by the window function described in the embodiment by performing the FIR filtering expressed by the above Equation (24) in the range of −0.5<w<0.

In addition, Reference Literature 1 describes sidelobe reduction technology called super-spatially variant apodization. By applying this technology to the above-described FIR filtering, it is also possible to reduce sidelobes while improving the frequency resolution.

Specifically, let a weight be wᵤ(m), image data be g(m), and image data obtained by FIR filtering g(m) be g′(m), FIR filtering is performed with these set in the relationship of the following Equations (25) to (27).

$$If {w}_{u} ( m ) < α , then g ’ ( m ) = g ( m ) + α [ g ( m - 1 ) + g ( m + 1 ) ] \qquad ( 25 )$$

$$If α \leq {w}_{u} ( m ) \leq 1 / 2 , the g ’ ( m ) = g ( m ) + {w}_{u} ( m ) [ g ( m - 1 ) + g ( m + 1 ) ] \qquad ( 26 )$$

$$If 1 / 2 < {w}_{u} ( m ) , then g ’ ( m ) = g ( m ) + ( 1 / 2 ) [ g ( m - 1 ) + g ( m + 1 ) ] \qquad ( 27 )$$

Note that, in the above Equations (25) and (26), α is a real number set within −0.5≤α≤0 and is set depending on desired performance. The FIR filtering described above can not only reduce sidelobes but also improve the frequency resolution.

As described above, in the signal processing device 1 according to the fourth embodiment, the window function wₚ(x) has a characteristic shape in which the central portion is recessed as compared with both end portions. As a result, the window function wₚ(x) can improve the frequency resolution as compared with that by a rectangular window function.

In the signal processing device 1 according to the fourth embodiment, out of a signal obtained by frequency-converting the signal extracted from the input signal having been multiplied by the window function, the signal output unit 14 may extract and outputs a signal having the minimum strength. This makes it possible to reduce the sidelobes while improving the frequency resolution.

In the signal processing device 1 according to the fourth embodiment, out of a signal obtained by frequency-converting the signal extracted from the input signal having been multiplied by the window function and a signal obtained by frequency-converting the input signal, the signal output unit extracts and outputs a signal having the minimum strength. This makes it possible to reduce the sidelobes while improving the frequency resolution.

In the signal processing device 1 according to the fourth embodiment, the frequency conversion unit 13 performs frequency conversion on the input signal, and the signal output unit 14 extracts a frequency-converted specific signal from the frequency-converted input signal using the finite impulse response filter set in such a manner that both the frequency resolution and the reduction amount of the sidelobes fall within the allowable ranges. It is possible to perform the FIR filtering capable of extracting a signal that reduces sidelobes while improving the frequency resolution.

Note that it is possible to include a combination of the embodiments or modification of any component of each of the embodiments or to omit any component in each of the embodiments.

### INDUSTRIAL APPLICABILITY

The signal processing device according to the present disclosure can be used for a radar system, for example.

### REFERENCE SIGNS LIST

1: signal processing device, 2: input signal storage unit, 3: output signal storage unit, 11: signal acquisition unit, 12: signal extraction unit, 13: frequency conversion unit, 14: signal output unit

1. A signal processing device comprising:
a processor; and
a memory storing a program, upon executed by the processor, to perform a process:
to acquire an input signal;
to extract a specific signal by multiplying the input signal by a window function;
to perform frequency conversion on the extracted signal; and
to output the frequency-converted signal,
wherein the window function comprises a synthesis of one or a plurality of cosine function terms, and
the window function is obtained by multiplying a negative coefficient to the cosine function term selected from one or the plurality of cosine function terms so that zero value is set at a center of the window range and a peak power of a sidelobe corresponding to the cosine function term in a frequency domain is reduced, a reduction of a frequency resolution is suppressed, or both thereof more than that of multiplying positive values to all of the cosine function terms.

2. The signal processing device according to claim 1,
wherein the window function does not include the cosine function term of an order that widens a main lobe as a value of a term increases that is the cosine function term corresponding to the main lobe which contributes to deterioration of frequency resolution in one or a plurality of the cosine function terms which composes the window function.

3. The signal processing device according to claim 1,
wherein the window function reduces a peak power of a sidelobe by superimposing a main lobe corresponding to the cosine function term in frequency domain on the sidelobe corresponding to the cosine function term having a different order than that of the cosine function term.

4. The signal processing device according to claim 1,
wherein the window function is obtained by determining the cosine function term of each degree corresponding to the main lobe so that the peak power of the sidelobe is reduced by superimposing the main lobe.

5. The signal processing device according to claim 4,
wherein the window function does not comprise a constant term but comprises the cosine function term.

6. The signal processing device according to claim 1,
wherein the window function has a characteristic shape in which function values at both end portions of the window are larger than 0 and a central portion is recessed as compared with both end portions.

7. The signal processing device according to claim 1,
wherein the process extracts and outputs a signal having minimum intensity from a signal obtained by performing frequency conversion on the signal extracted from the input signal by multiplying the window function.

8. The signal processing device according to claim 1,
wherein the process extracts and outputs a signal having minimum intensity out of a signal obtained by performing frequency conversion on the signal extracted from the input signal by multiplying the window function and a signal obtained by frequency-converting the input signal.

9. The signal processing device according to claim 1,
wherein the process performs frequency conversion on the input signal, and
the process extracts a frequency-converted specific signal from the frequency-converted input signal using a finite impulse response filter set in such a manner that the peak power of the sidelobe corresponding to the cosine function term in the frequency domain is reduced and outputs the specific signal.

10. A signal processing method of a signal processing device, the signal processing method comprising:
acquiring an input signal;
extracting a specific signal by multiplying the input signal by a window function;
performing frequency conversion on the extracted signal; and
outputting the frequency-converted signal,
wherein the window function comprises a synthesis of one or a plurality of cosine function terms, and
the window function is obtained by multiplying a negative coefficient to the cosine function term selected from one or the plurality of cosine function terms so that zero value is set at a center of the window range and a peak power of a sidelobe corresponding to the cosine function term in a frequency domain is reduced, a reduction of a frequency resolution is suppressed, or both thereof more than that of multiplying positive values to all of the cosine function terms.

11. The signal processing method according to claim 10,
wherein the window function does not include the cosine function term of an order that widens a main lobe as a value of a term increases that is the cosine function term corresponding to the main lobe which contributes to deterioration of frequency resolution in one or a plurality of the cosine function terms which composes the window function.

12. The signal processing method according to claim 10,
wherein the window function reduces a peak power of a sidelobe by superimposing a main lobe corresponding to the cosine function term in the frequency domain on the sidelobe corresponding to the cosine function term having a different order than that of the cosine function term.

13. The signal processing method according to claim 10,
wherein the window function is obtained by determining the cosine function term of each degree corresponding to the main lobe so that the peak power of the sidelobe is reduced by superimposing the main lobe.

14. The signal processing method according to claim 13,
wherein the window function does not comprise a constant term but comprises the cosine function term.

15. The signal processing method according to claim 10,
wherein the window function has a characteristic shape in which function values at both end portions of the window are larger than 0 and a central portion is recessed as compared with both end portions.

16. The signal processing method according to claim 10,
wherein the method extracts and outputs a signal having minimum intensity from a signal obtained by performing frequency conversion on the signal extracted from the input signal by multiplying the window function.

17. The signal processing method according to claim 10,
wherein the method extracts and outputs a signal having minimum intensity out of a signal obtained by performing frequency conversion on the signal extracted from the input signal by multiplying the window function and a signal obtained by frequency-converting the input signal.

18. The signal processing method according to claim 10,
wherein the method performs frequency conversion on the input signal, and
the method extracts a frequency-converted specific signal from the frequency-converted input signal using a finite impulse response filter set in such a manner that the peak power of the sidelobe corresponding to the cosine function term in the frequency domain is reduced and outputs the specific signal.
